(19) United States
(12) Patent Application Publication
(10) Pub. No.: US 2023/0197742 A1
(43) Pub. Date: Jun. 22, 2023

(54) IMAGE SENSOR AND METHOD FOR FABRICATING THE SAME

(71) Applicant: Samsung Electronics Co., Ltd., Suwon-si (KR)

(72) Inventors: Jeong Soon KANG, Gumi-si (KR); Chang Yong UM, Seoul (KR); Jeong Jin LEE, Seoul (KR)

(73) Assignee: Samsung Electronics Co., Ltd., Suwon-si (KR)

(21) Appl. No.: 18/061,628

(22) Filed: Dec. 5, 2022

(30) Foreign Application Priority Data
Dec. 21, 2021 (KR) 10-2021-0183702

(51) Int. Cl. H01L 27/146

(52) U.S. Cl. CPC H01L 27/14616; H01L 27/14645

(57) ABSTRACT

An image sensor includes a first semiconductor substrate, a photoelectric conversion region in the first semiconductor substrate, and a buried insulating film on the first semiconductor substrate. The buried insulating film covers a first region of the first semiconductor substrate and exposes a second region of the first semiconductor substrate. The sensor includes a second semiconductor substrate on the buried insulating film, an operating gate structure defining a first channel of a first conductive type in the second semiconductor substrate, and a transfer gate structure defining a second channel of a second conductive type different from the first conductive type in the second region of the first semiconductor substrate.

### CROSS-REFERENCE TO RELATED APPLICATION

This application claims priority from Korean Patent Application No. 10-2021-0183702 filed on Dec. 21, 2021, in the Korean Intellectual Property Office, and all the benefits accruing therefrom under 35 U.S.C. 119, the contents of which in its entirety are herein incorporated by reference.

### BACKGROUND

Some example embodiments of the inventive concepts relate to an image sensor and/or a method for fabricating the same. More specifically, some example embodiments relate to an image sensor using an SOI (Silicon on Insulator) substrate and/or a method for fabricating the same.

An image sensor is one of various semiconductor elements that convert optical information into an electric signal. Such an image sensor may include a charge coupled device (CCD) image sensor and a CMOS (Complementary Metal-Oxide Semiconductor) image sensor.

The image sensor may be configured in the form of a package. The package may be formed by a configuration which protects the image sensor and allows light to enter a photo-receiving surface or a sensing region of the image sensor.

A backside illumination (BSI) image sensor in which incident light is irradiated from a back side of a semiconductor substrate so that pixels formed in the image sensor have improved photo-receiving efficiency and sensitivity has been studied.

### SUMMARY

Some example embodiments of the inventive concepts provide an image sensor in which pixels can be reduced or miniaturized and the quality is improved.

Some example embodiments of the inventive concepts provide a method for fabricating an image sensor in which pixels can be reduced miniaturized and the quality is improved.

However, example embodiments are not limited to those set forth herein. The above and other example embodiments of the inventive concepts will become more apparent by referencing the detailed description of some example embodiments given below.

According to some example embodiments of the inventive concepts, an image sensor includes a first semiconductor substrate, a photoelectric conversion region in the first semiconductor substrate, and a buried insulating film on the first semiconductor substrate. The buried insulating film covers a first region of the first semiconductor substrate and exposes a second region of the first semiconductor substrate. The sensor includes a second semiconductor substrate on the buried insulating film, an operating gate structure defining a first channel of a first conductive type in the second semiconductor substrate, and a transfer gate structure defining a second channel of a second conductive type different from the first conductive type in the second region of the first semiconductor substrate.

According to another example embodiment, an image sensor includes a first semiconductor substrate including a first surface and a second surface opposite to each other, a photoelectric conversion region in the first semiconductor substrate, and a buried insulating film on the first surface of the first semiconductor substrate. The buried insulating film covers a first region of the first semiconductor substrate and exposes a second region of the first semiconductor substrate. The sensor includes a second semiconductor substrate on the buried insulating film, an operating gate structure on the second semiconductor substrate, and a transfer gate structure on the second region of the first semiconductor substrate. At least a part of the transfer gate structure extends from the first surface of the first semiconductor substrate toward the photoelectric conversion region.

According to another example embodiment, an image sensor includes a p-type first semiconductor substrate including a first surface and a second surface opposite to each other, an element separation pattern defining a plurality of pixel regions in the first semiconductor substrate, an n-type photoelectric conversion region in the first semiconductor substrate of each of the pixel regions, and a buried insulating film on the first surface of the first semiconductor substrate. The buried insulating film covers a first region of the first semiconductor substrate and exposes a second region of the first semiconductor substrate. The sensor includes an n-type second semiconductor substrate on the buried insulating film, an operating gate structure defining a p-type channel in the second semiconductor substrate, a transfer gate structure defining an n-type channel in the second region of the first semiconductor substrate, and a first wiring structure on the first surface of the first semiconductor substrate. The first wiring structure is connected to the operating gate structure and the transfer gate structure. The sensor includes a microlens on the second surface of the first semiconductor substrate, with the microlens corresponding to each of the pixel regions. At least a part of the transfer gate structure extends from the first surface of the first semiconductor substrate toward the photoelectric conversion region.

### BRIEF DESCRIPTION OF THE DRAWINGS

The above and other example embodiments of the inventive concepts will become more apparent by describing in detail example embodiments thereof with reference to the attached drawings, in which:

FIG. 1 is an example block diagram for explaining an image sensor according to some example embodiments.

FIG. 2 is an example circuit diagram for explaining an image sensor according to some example embodiments.

FIG. 3 is a schematic layout diagram for explaining the unit pixel of the image sensor according to some example embodiments.

FIG. 4a is a schematic cross-sectional view taken along A-A of FIG. 3.

FIG. 4b is a schematic cross-sectional view taken along B-B of FIG. 3.

FIG. 4c is a schematic cross-sectional view taken along C-C of FIG. 3.

FIGS. 5a to 5c are various enlarged views for explaining a region S of FIG. 4a.

FIG. 6 is another example circuit diagram for explaining an image sensor according to some example embodiments.

FIG. 7 is a schematic layout diagram for explaining the image sensor according to FIG. 6.

FIG. 8 is an example layout diagram for explaining an image sensor according to some example embodiments.

FIG. 9 is a schematic cross-sectional view for explaining the image sensor of FIG. 8.

FIGS. 10, 11, 12, 13, 14, 15, 16, 17, 18, 19, 20, 21, 22, 23, 24 and 25 are intermediate step diagrams for explaining a method for fabricating an image sensor according to some example embodiments.

### DETAILED DESCRIPTION OF SOME EXAMPLE EMBODIMENTS

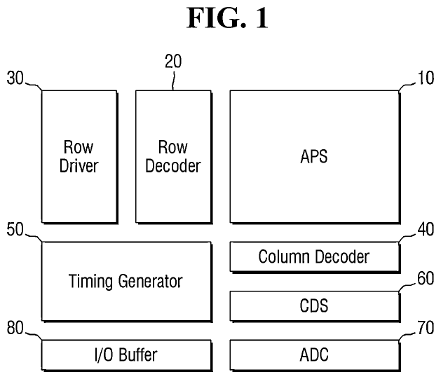

Hereinafter, an image sensor according to some example embodiments will be described referring to FIGS. 1 to 9.

FIG. 1 is an example block diagram for explaining an image sensor according to some example embodiments.

Referring to FIG. 1, the image sensor according to some example embodiments includes an active pixel sensor array (APS) 10, a row decoder 20, a row driver 30, a column decoder 40, a timing generator 50, a correlated double sampler (CDS) 60, an analog-to-digital converter (ADS) 70, and an I/O buffer 80.

The active pixel sensor array 10 includes a plurality of unit pixels arranged two-dimensionally, and may convert an optical signal into an electric signal. The active pixel sensor array 10 may be driven by a plurality of drive signals, such as a pixel selection signal, a reset signal and a charge transfer signal, from the row driver 30. Also, the electrical signal converted by the active pixel sensor array 10 may be provided to the correlated double sampler 60.

The row driver 30 may provide a large number of drive signals for driving a plurality of unit pixels to the active pixel sensor array 10 depending on the results decoded by the row decoder 20. When the unit pixels are disposed in the form of a matrix, the drive signals may be provided for each row.

The timing generator 50 may provide a timing signal and a control signal to the row decoder 20 and the column decoder 40.

The correlated double sampler (CDS) 60 may receive, hold and sample the electrical signals generated by the active pixel sensor array 10. The correlated double sampler 60 may doubly sample a specific noise level and a signal level due to an electrical signal, and output a difference level corresponding to a difference between the noise level and the signal level.

The analog-to-digital converter (ADC) 70 may convert the analog signal corresponding to the difference level, which is output from the correlated double sampler 60, into a digital signal and output the digital signal.

The I/O buffer 80 latches the digital signal, and the latched signal may sequentially output the digital signal to an image signal processing unit (not shown) depending on the decoding result from the column decoder 40.

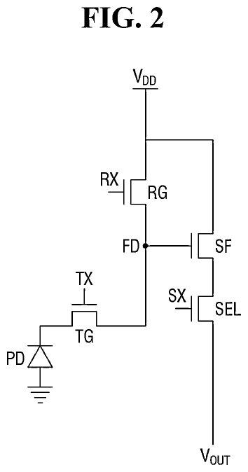

FIG. 2 is an example circuit diagram for explaining an image sensor according to some example embodiments.

Referring to FIG. 2, each unit pixel of the image sensor according to some example embodiments may include a photoelectric conversion element PD, a transfer transistor TG, a floating diffusion region FD, a reset transistor RG, a source follower transistor SF, and a selection transistor SEL.

The photoelectric conversion element PD may generate electric charges in proportion to an amount of light that is incident from the outside. The photoelectric conversion element PD may be coupled with the transfer transistor TG, which transfers the generated and accumulated electric charges to the floating diffusion region FD. Since the floating diffusion region FD is a region which converts the electric charges into a voltage, and has a parasitic capacitance, the electric charges may be accumulatively stored therein.

One end of the transfer transistor TG may be connected to the photoelectric conversion element PD, and the other end of the transfer transistor TG may be connected to the floating diffusion region FD. The transfer transistor TG may be formed by a transistor that is driven by a desired (or, alternatively predetermined) bias (e.g., a transfer signal TX). That is, the transfer transistor TG may transmit the electric charges, which are generated from the photoelectric conversion element PD, to the floating diffusion region FD in accordance with the transfer signal TX.

The source follower transistor SF may amplify a change in electrical potential of the floating diffusion region FD to which the electric charges are sent from the photoelectric conversion element PD and output it to an output line V_{OUT}. When the source follower transistor SF is turned on, a desired (or, alternatively predetermined) electrical potential provided to a drain of the source follower transistor SF, for example, a power supply voltage V_{DD}, may be sent to a drain region of the selection transistor SEL.

The selection transistor SEL may select a unit pixel to be read on a row basis. The selection transistor SEL may be made up of a transistor that is driven by a selection line that applies a desired (or, alternatively predetermined) bias (e.g., a row selection signal SX).

The reset transistor RG may periodically reset the floating diffusion region FD. The reset transistor RG may be made up of a transistor that is driven by a reset line that applies a desired (or, alternatively predetermined) bias (e.g., a reset signal RX). When the reset transistor RG is turned on by the reset signal RX, a desired (or, alternatively predetermined) electrical potential provided to the drain of the reset transistor RG, for example, the power supply voltage V_{DD}, may be sent to the floating diffusion region FD.

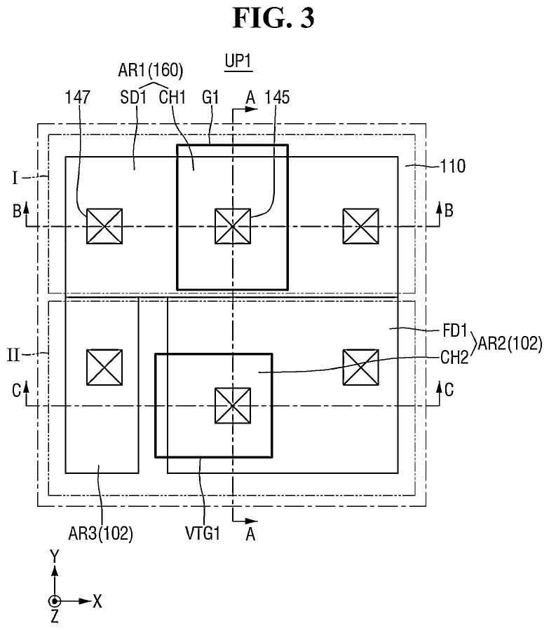

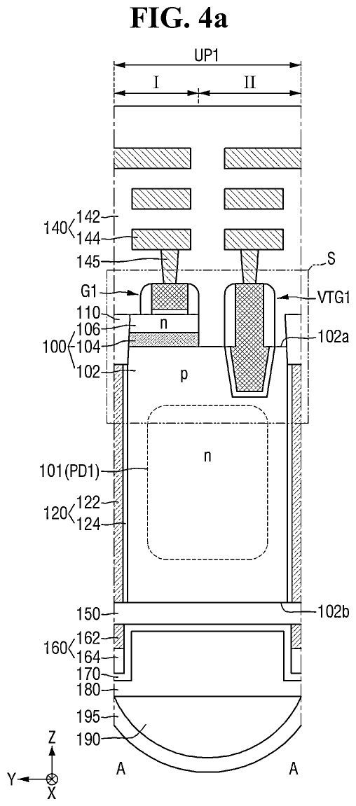

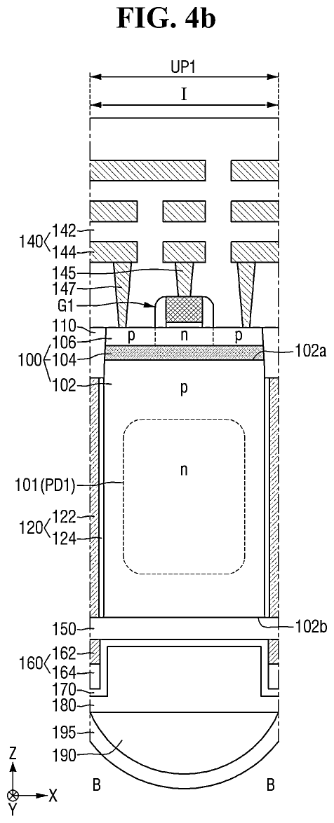

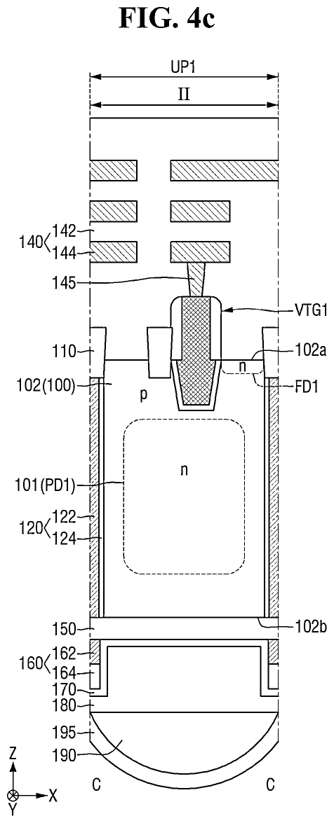

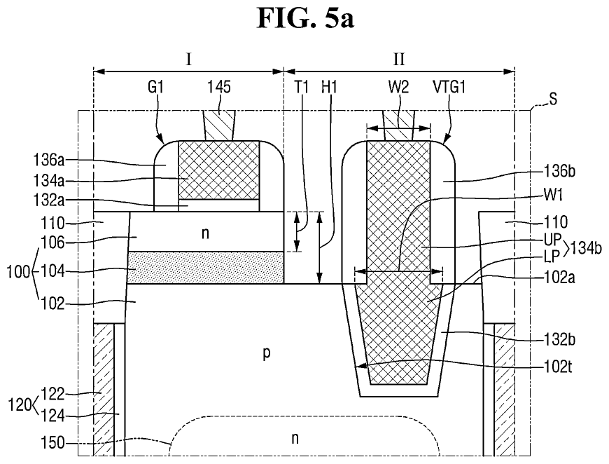

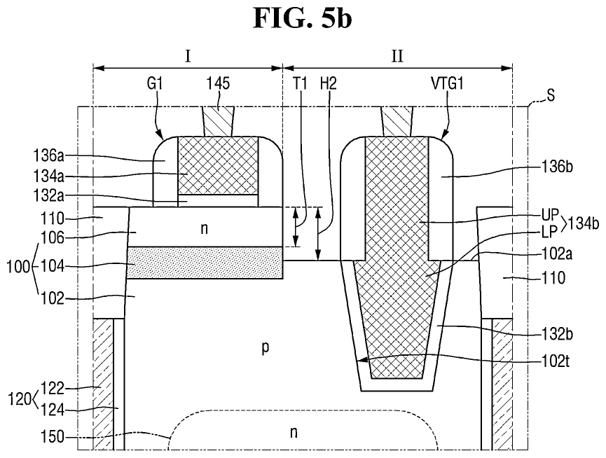

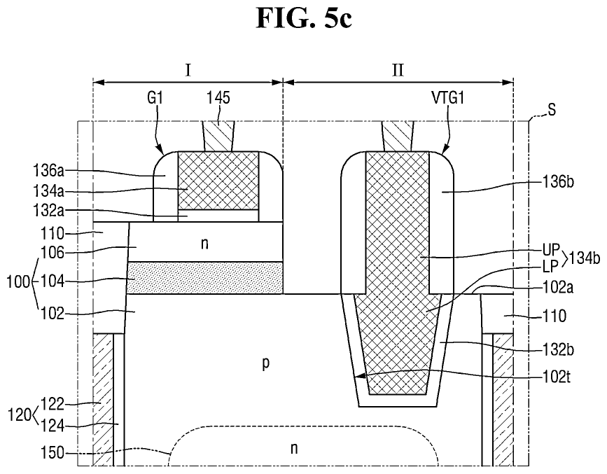

FIG. 3 is a schematic layout diagram for explaining the unit pixel of the image sensor according to some example embodiments. FIG. 4a is a schematic cross-sectional view taken along A-A of FIG. 3. FIG. 4b is a schematic cross-sectional view taken along B-B of FIG. 3. FIG. 4c is a schematic cross-sectional view taken along C-C of FIG. 3. FIGS. 5a to 5c are various enlarged views for explaining a region S of FIG. 4a.

The image sensor according to some example embodiments may include a plurality of unit pixels. The plurality of unit pixels may be arranged two-dimensionally (e.g., in the form of a matrix) in a plane including, for example, a first direction X and a second direction Y. For convenience of explanation, FIGS. 3 to 5c mainly describe one unit pixel (hereinafter, a first unit pixel UP1) of the image sensor according to some example embodiments.

Referring to FIGS. 3 to 5c, the image sensor according to some example embodiments includes a cell substrate 100, a photoelectric conversion region 101, element separation patterns 110 and 120, a first operating gate structure G1, a first transfer gate structure VTG1, a first wiring structure 140, a surface insulating film 150, a grid pattern 160, a color filter 180, and a microlens 190.

The cell substrate 100 may be an SOI (Silicon on Insulator) substrate. For example, the cell substrate 100 may include a first semiconductor substrate 102, and a buried insulating film 104 and a second semiconductor substrate 106 sequentially stacked on the first semiconductor substrate 102.

The first semiconductor substrate 102 may be a bulk semiconductor substrate. The first semiconductor substrate 102 may be a silicon substrate or may include other materials, for example, silicon germanium, indium antimonide, lead tellurium compounds, indium arsenic, indium phosphide, gallium arsenide or gallium antimonide, but example embodiments are not limited thereto. The first semiconductor substrate 102 may be an epitaxial layer formed on a base substrate. For convenience of explanation, the first semiconductor substrate 102 will be described as a bulk silicon (bulk Si) substrate below.

The first semiconductor substrate 102 may include a first surface 102a and a second surface 102b that are opposite to each other. The first surface 102a may be referred to as a front side of the first semiconductor substrate 102, and the second surface 102b may be referred to as a back side of the first semiconductor substrate 102. In some example embodiments, the first semiconductor substrate 102 may be a photo-receiving surface on which light is incident. That is, the image sensor according to some example embodiments may be a backside illumination (BSI) image sensor.

In some example embodiments, the first semiconductor substrate 102 may have a first conductive type. For example, the first semiconductor substrate 102 may include a first conductive type of impurities. In the following description, the first semiconductor substrate 102 will be described as a p-type. For example, the first semiconductor substrate 102 may include p-type impurity. The p-type impurity may include, for example, but is not limited to, at least one of boron (B), aluminum (Al), indium (In) and gallium (Ga).

The buried insulating film 104 may be formed on the first surface 102a of the first semiconductor substrate 102. The buried insulating film 104 may include, but is not limited to, an insulating material, for example, silicon oxide.

The buried insulating film 104 may cover a part of the first semiconductor substrate 102 and expose the other part of the first semiconductor substrate 102. In the following description, the region in which the buried insulating film 104 covers the first semiconductor substrate 102 may be referred to as a first region I, and the region in which the buried insulating film 104 exposes the first semiconductor substrate 102 may be referred to as a second region II.

The first surface 102a of the second region II of the first semiconductor substrate 102 may be formed to be lower than the upper surface of the buried insulating film 104. Although the first surface 102a of the second region II of the first semiconductor substrate 102 is only shown as being disposed on the same plane as (that is, coplanar or substantially coplanar with) the first surface 102a of the first region I of the first semiconductor substrate 102, this is merely an example. As another example, the first surface 102a of the second region II of the first semiconductor substrate 102 may be formed to be lower than the first surface 102a of the first region I of the first semiconductor substrate 102.

The second semiconductor substrate 106 may be formed on the buried insulating film 104. That is, the buried insulating film 104 may be interposed between the first semiconductor substrate 102 and the second semiconductor substrate 106. The second semiconductor substrate 106 may be a silicon substrate or may include other materials, for example, silicon germanium, indium antimonide, lead tellurium compounds, indium arsenide, indium phosphide, gallium arsenide or gallium antimonide, but example embodiments are not limited thereto. The second semiconductor substrate 106 may be an epitaxial layer formed on the buried insulating film 104. As an example, the second semiconductor substrate 106 may be a silicon (Si) substrate, a silicon germanium (SiGe) substrate, etc.

The second semiconductor substrate 106 may cover the upper surface of the buried insulating film 104. Further, the second semiconductor substrate 106 may expose the second region II of the first semiconductor substrate 102. In some example embodiments, the side surface of the buried insulating film 104 and the side surface of the second semiconductor substrate 106 may be continuous.

In some example embodiments, the second semiconductor substrate 106 may have a second conductive type that is different from the first conductive type. For example, the second semiconductor substrate 106 may include a second conductive type of impurity. In the following description, the second semiconductor substrate 106 will be described as an n-type. For example, the second semiconductor substrate 106 may include n-type impurity. The n-type impurity may include, for example, but is not limited to, at least one of phosphorus (P), arsenic (As), antimony (Sb) and bismuth (Bi).

In some embodiments, a thickness (e.g., T1 of FIG. 5a) of the second semiconductor substrate 106 may be about 30 nm or less. For example, the thickness T1 of the second semiconductor substrate 106 may be in a range from about 10 nm to about 30 nm (or more or less). The second semiconductor substrate 106 may form an SOI (Silicon on Insulator) transistor together with a first operating gate structure G1 to be described below

In some example embodiments, a step (e.g., H1 of FIG. 5a) between the second region II of the first semiconductor substrate 102 and the second semiconductor substrate 106 may be about 50 nm or less. For example, the step between the second region II of the first semiconductor substrate 102 and the second semiconductor substrate 106 may be about 10 nm to about 50 nm (or more or less).

The photoelectric conversion region 101 may be formed in the first semiconductor substrate 102 of the first unit pixel UP1. The photoelectric conversion region 101 may correspond to the photoelectric conversion element PD of FIG. 2. That is, the photoelectric conversion region 101 may generate electric charges in proportion to the amount of light incident from the outside.

The photoelectric conversion region 101 may have a second conductive type different from the first conductive type. For example, the photoelectric conversion region 101 is formed by ion-implanting n-type impurities into the first semiconductor substrate 102 that is the p-type.

In some example embodiments, the photoelectric conversion region 101 may have a potential gradient in a third direction Z that intersects the first direction X and the second direction Y. For example, the impurity concentration of the photoelectric conversion region 101 may increase from the first surface 102a toward the second surface 102b.

The element separation patterns 110 and 120 may define a plurality of unit pixels in the cell substrate 100. For example, at least a part of the element separation patterns 110 and 120 may be formed in the cell substrate 100 to surround the first unit pixel UP1. For example, the element separation patterns 110 and 120 may be formed by burying an insulating material in a trench formed by patterning the cell substrate 100.

In some example embodiments, the element separation patterns 110 and 120 may include a first separation pattern 110 and a second separation pattern 120.

The first separation pattern 110 may extend from the upper surface of the second semiconductor substrate 106 toward the second surface 102b of the first semiconductor substrate 102. Further, the lower surface of the first separation pattern 110 may be formed to be lower than the first surface 102a of the first semiconductor substrate 102. For example, the first separation pattern 110 may be formed by burying an insulating material in a shallow trench formed by patterning the first semiconductor substrate 102, the buried insulating film 104, and the second semiconductor substrate 106. The first separation pattern 110 may include, for example, but is not limited to, at least one of silicon oxide, silicon nitride, silicon oxynitride, and combinations thereof.

Such a first separation pattern 110 may define active regions AR1, AR2, and AR3 in the first unit pixel UP1. For example, the first separation pattern 110 may surround the active regions AR1, AR2, and AR3 from a plan viewpoint.

The active regions AR1, AR2, and AR3 may include a first active region AR1 defined in the first region I, and second and third active regions AR2 and AR3 defined in the second region II. Since the first region I of the first semiconductor substrate 102 is covered with the buried insulating film 104 and the second semiconductor substrate 106, the first active region AR1 may be defined in the second semiconductor substrate 106. Since the second region II of the first semiconductor substrate 102 is exposed by the buried insulating film 104 and the second semiconductor substrate 106, the second and third active regions AR2 and AR3 may each be defined in the second region II of the first semiconductor substrate 102. Further, since the first surface 102a of the first semiconductor substrate 102 is formed to be lower than the upper surface of the buried insulating film 104, the second and third active regions AR2 and AR3 may be electrically separated from the second active region AR1 by the buried insulating film 104.

In some example embodiments, the width of the first separation pattern 110 may decrease toward the second surface 102b of the first semiconductor substrate 102. This may be due to the characteristics of the etching process for forming the first separation pattern 110.

In some example embodiments, the upper surface of the first separation pattern 110 adjacent to the first region I of the first semiconductor substrate 102 may be disposed on the same or substantially the same plane as (e.g., coplanar or substantially with) the upper surface of the second semiconductor substrate 106. In the present specification, the term “the same” means not only exactly the same thing, but also includes minute differences that may occur due to process margins and the like.

In some example embodiments, the upper surface of the first separation pattern 110 adjacent to the second region II of the first semiconductor substrate 102 may protrude from the first surface 102a of the first semiconductor substrate 102. For example, the upper surface of the first separation pattern 110 adjacent to the second region II of the first semiconductor substrate 102 may be disposed on the same or substantially the same plane as the upper surface of the first separation pattern 110 adjacent to the first region I of the first semiconductor substrate 102.

The second separation pattern 120 may extend from the lower surface of the first separation pattern 110 toward the second surface 102b of the first semiconductor substrate 102. For example, the second separation pattern 120 may be formed by burying an insulating material in a deep trench formed by patterning the first semiconductor substrate 102. The second separation pattern 120 may include, for example, but is not limited to, at least one of silicon oxide, silicon nitride, silicon oxynitride, and combinations thereof.

Although the width of the second separation pattern 120 is shown as being constant, this is only an example. In some other example embodiments, the width of the second separation pattern 120 may decrease toward the second surface 102b of the first semiconductor substrate 102. In yet some other example embodiments, the width of the second separation pattern 120 may increase toward the second surface 102b of the first semiconductor substrate 102.

In some example embodiments, the second separation pattern 120 may completely penetrate the first semiconductor substrate 102. For example, the lower surface of the second separation pattern 120 may be disposed on the same or substantially the same plane as the second surface 102b of the first semiconductor substrate 102.

In some example embodiments, the second separation pattern 120 may include a filling pattern 122 and a spacer film 124.

The filling pattern 122 may extend from the lower surface of the first separation pattern 110 toward the second surface 102b of the first semiconductor substrate 102. The filling pattern 122 may include, but is not limited to, conductive materials, for example, polysilicon (poly Si). In some example embodiments, a ground voltage or a negative voltage may be applied to the filling pattern 122. Such a filling pattern 122 may inhibit or prevent the electric charges generated by ESD (electrostatic discharge) or the like from being accumulated on the surface of the first semiconductor substrate 102 (e.g., the second surface 102b) to effectively inhibit or prevent an ESD bruise defect.

The spacer film 124 may extend along the side surfaces of the filling pattern 122. The spacer film 124 may include, but is not limited to, insulating materials, for example, at least one of silicon oxide, aluminum oxide, tantalum oxide, and combinations thereof. Such a spacer film 124 may be interposed between the filling pattern 122 and the first semiconductor substrate 102 to electrically separate the filling pattern 122 and the first semiconductor substrate 102.

The first operating gate structure G1 may be formed on the second semiconductor substrate 106. For example, the first operating gate structure G1 may be formed on the first active region AR1. As shown in FIG. 3, the first operating gate structure G1 may define a first channel region CH1 in the first active region AR1 that overlaps the first operating gate structure G1. Further, a source/drain region SD1 may be formed in the first active region AR1 adjacent to the side surface of the first operating gate structure G1. The source/drain region SD1 may have the first conductive type. For example, the source/drain region SD1 may be formed by ion-implanting the p-type impurities into the n-type second semiconductor substrate 106.

When the first operating gate structure G1 is turned on, the first operating gate structure G1 may form a channel of the first conductive type in the second semiconductor substrate 106 (or in the first channel region CH1 of the first active region AR1). For example, the first operating gate structure G1 may form a p-type channel in the n-type second semiconductor substrate 106. That is, the first operating gate structure G1 and the second semiconductor substrate 106 may form a PMOS transistor.

In some example embodiments, the second semiconductor substrate 106 may form a silicon on insulator (SOI) transistor. The second semiconductor substrate 106 may form a fully depleted SOI (FDSOI) transistor, or may form a partially depleted SOI (PDSOI) transistor.

As shown in FIG. 5a, the first operating gate structure G1 may include a first gate dielectric film 132a, a first gate electrode 134a, and a first gate spacer 136a. The first gate dielectric film 132a may be interposed between the second semiconductor substrate 106 and the first gate electrode 134a. The first gate spacer 136a may extend along the side surfaces of the first gate electrode 134a.

In some example embodiments, the first operating gate structure G1 and the second semiconductor substrate 106 may form a planar transistor. For example, the first gate dielectric film 132a may conformally extend along the upper surface of the second semiconductor substrate 106. The first gate electrode 134a may be stacked on the first gate dielectric film 132a. The first gate spacer 136a may extend along the side surfaces of the first gate dielectric film 132a and the side surfaces of the first gate electrode 134a.

In the image sensor according to some example embodiments, the first operating gate structure G1 and the second semiconductor substrate 106 may form at least one of a reset transistor (e.g., RG of FIG. 2), a source follower transistor (e.g., SF of FIG. 2), and a selection transistor (e.g., SEL of FIG. 2). For example, the first operating gate structure G1 may correspond to one of the gate of the reset transistor RG, the gate of the source follower transistor SF, and the gate of the selection transistor SEL.

Although only one first operating gate structure G1 is shown as being disposed in the first unit pixel UP1, in other example embodiments a plurality of first operating gate structures G1 having different functions may be disposed in the first unit pixel UP1. For example, at least two transistors among the reset transistor (e.g., RG of FIG. 2), the source follower transistor (e.g., SF of FIG. 2), and the selection transistor (e.g., SEL of FIG. 2) may be disposed in the first unit pixel UP1.

The first transfer gate structure VTG1 may be formed on the second region II of the first semiconductor substrate 102. For example, the first transfer gate structure VTG1 may be formed on the second active region AR2. In the image sensor according to some example embodiments, the first transfer gate structure VTG1 and the second region II of the first semiconductor substrate 102 may form a transfer transistor (e.g., TG of FIG. 2). For example, the first transfer gate structure VTG1 may correspond to the gate of the transfer transistor TG.

As shown in FIG. 3, the first transfer gate structure VTG1 may define the second channel region CH2 in the second active region AR2 that overlaps the first transfer gate structure VTG1. Further, a first floating diffusion region FD1 may be formed in the second active region AR2 adjacent to the side surface of the first transfer gate structure VTG1. The first floating diffusion region FD1 may have a second conductive type. For example, the first floating diffusion region FD1 may be formed by ion-implanting the n-type impurities into the p-type first semiconductor substrate 102. When the first transfer gate structure VTG1 is turned on, the electric charges generated from the photoelectric conversion region 101 may be transmitted to the first floating diffusion region FD1 through the second channel region CH2.

Further, when the first transfer gate structure VTG1 is turned on, the first transfer gate structure VTG1 may form a channel of the second conductive type in the second region II of the first semiconductor substrate 102 (or in the second channel region CH2 of the second active region AR2). For example, the first transfer gate structure VTG1 may form an n-type channel in the p-type first semiconductor substrate 102. That is, the first transfer gate structure VTG1 and the first semiconductor substrate 102 may form an NMOS transistor.

As shown in FIG. 5a, the first transfer gate structure VTG1 may include a second gate dielectric film 132b, a second gate electrode 134b, and a second gate spacer 136b. The second gate dielectric film 132b may be interposed between the first semiconductor substrate 102 and the second gate electrode 134b. The second gate spacer 136b may extend along the side surfaces of the second gate electrode 134b.

In some example embodiments, at least a part of the first transfer gate structure VTG1 may overlap the photoelectric conversion region 101 in the third direction Z.

In some example embodiments, the first transfer gate structure VTG1 may form a vertical transfer gate. The vertical transfer gate may form a transistor whose channel length extends in the vertical direction (e.g., the third direction Z). For example, the second region II of the first semiconductor substrate 102 may include a substrate trench 102t that extends from the first surface 102a of the first semiconductor substrate 102 toward the second surface 102b of the first semiconductor substrate 102. At least a part of the substrate trench 102t may overlap the photoelectric conversion region 101 in the third direction Z. At least a part of the first transfer gate structure VTG1 may fill the substrate trench 102t. Therefore, the first transfer gate structure VTG1 which at least partially extends from the first surface 102a of the first semiconductor substrate 102 toward the photoelectric conversion region 101 may be formed.

In some example embodiments, the second gate dielectric film 132b may conformally extend along the profiles of side surfaces and the lower surface of the substrate trench 102t.

In some example embodiments, the second gate electrode 134b may include a first portion LP disposed in a second region II of the first semiconductor substrate 102, and a second portion UP that protrudes from the first surface 102a of the first semiconductor substrate 102. For example, the first portion LP of the second gate electrode 134b may be formed on the second gate dielectric film 132b to fill the remaining region of the substrate trench 102t. The second portion UP of the second gate electrode 134b may protrude from the upper surface of the first portion LP of the second gate electrode 134b.

In some example embodiments, the width (e.g., W1 of FIG. 5a) of the first portion LP of the second gate electrode 134b may be greater than the width (e.g., W2 of FIG. 5a) of the second portion UP of the second gate electrode 134b.

In some example embodiments, the second gate spacer 136b may extend along the side surfaces of the second portion UP of the second gate electrode 134b. The second gate spacer 136b may cover the upper surface of the first portion LP of the second gate electrode 134b.

In some example embodiments, the upper surface of the first operating gate structure G1 and the upper surface of the first transfer gate structure VTG1 may be disposed on the same or substantially the same plane. For example, the uppermost surface of the first gate electrode 134a and the uppermost surface of the second gate electrode 134b may be disposed on the same or substantially the same plane.

In some example embodiments, the first operating gate structure G1 and the first transfer gate structure VTG1 may be formed at the same or substantially the same level. As used herein, the term “same level” means formation by the same or substantially the same fabricating process.

The first gate electrode 134a and the second gate electrode 134b may each include, but are not limited to, at least one of a conductive material, for example, polysilicon (poly Si) doped with impurities, a metal silicide such as cobalt silicide, a metal nitride such as titanium nitride, and metals such as tungsten, copper and aluminum. As an example, the first gate electrode 134a and the second gate electrode 134b may each include a polysilicon film.

The first gate dielectric film 132a and the second gate dielectric film 132b may each include, for example, but are not limited to, at least one of silicon oxide, silicon nitride, silicon oxynitride and a high dielectric constant (high-k) material having a higher dielectric constant than silicon oxide. As an example, the first gate dielectric film 132a and the second gate dielectric film 132b may each include a silicon oxide film.

The first gate spacer 136a and the second gate spacer 136b may each include, for example, but are not limited to, at least one of silicon oxide, silicon nitride, silicon oxynitride, and a combination thereof. As an example, the first gate spacer 136a and the second gate spacer 136b may each include a silicon nitride film.

In some example embodiments, a ground voltage may be applied to the third active region AR3. For example, the third active region AR3 may be formed by ion-implanting a p-type impurity of high-concentration into the p-type first semiconductor substrate 102.

The first wiring structure 140 may be formed on the first surface 102a of the first semiconductor substrate 102. The first wiring structure 140 may include a plurality of wiring patterns. For example, the first wiring structure 140 may include a first inter-wiring insulating film 142, and a first wiring pattern 144 in the first inter-wiring insulating film 142. In FIGS. 4a to 4c, the number of layers and the arrangement of the first wiring pattern 144 are for purposes of illustrating an example embodiment, and other example embodiments may include different numbers of layers and different arrangements of the first wiring pattern 144.

The first wiring structure 140 may be connected to the first operating gate structure G1 and the first transfer gate structure VTG1. For example, a gate contact 145 that extends in the third direction Z and connects the first operating gate structure G1 and/or the first transfer gate structure VTG1 and the first wiring pattern 144 may be formed in the first inter-wiring insulating film 142. Therefore, the first operating gate structure G1 and the first transfer gate structure VTG1 may be electrically connected to the first wiring pattern 144, respectively.

The first wiring structure 140 may be connected to the first floating diffusion region FD1 and the source/drain region SD1. For example, a source/drain contact 147 that extends in the third direction Z and connects the first floating diffusion region FD1 and/or the source/drain region SD1 and the first wiring pattern 144 may be formed in the first inter-wiring insulating film 142. Therefore, the first floating diffusion region FD1 and the source/drain region SD1 may each be electrically connected to the first wiring pattern 144.

The surface insulating film 150 may be formed on the second surface 102b of the first semiconductor substrate 102. The surface insulating film 150 may extend along the second surface 102b of the first semiconductor substrate 102. The surface insulating film 150 may include, but is not limited to, insulating materials, for example, silicon oxide, silicon nitride, silicon oxynitride, aluminum oxide, hafnium oxide, and combinations thereof.

In some example embodiments, the surface insulating film 150 may be formed of a multiple film. For example, the surface insulating film 150 may include an aluminum oxide film, a hafnium oxide film, a silicon oxide film, a silicon nitride film, and a hafnium oxide film sequentially stacked on the second surface 102b of the first semiconductor substrate 102, but example embodiments are not limited thereto.

The surface insulating film 150 functions as an antireflection film, and may inhibit or prevent reflection of light that is incident on the second surface 102b of the first semiconductor substrate 102. Therefore, the photo-receiving rate of the photoelectric conversion region 101 may be improved. Further, the surface insulating film 150 functions as a flattening film and may contribute to the formation of a color filter 180 and a microlens 190, which will be described later, at a uniform height.

The color filter 180 may be formed on the surface insulating film 150. The color filter 180 may be arranged to correspond to each unit pixel (e.g., the first unit pixel UP1). That is, the plurality of color filters 180 may be arranged two-dimensionally (e.g., in the form of a matrix) in a plane including the first direction X and the second direction Y.

The color filter 180 may have various colors depending on the unit pixel. For example, the color filter 180 may include a red color filter, a green color filter, a blue color filter, a yellow filter, a magenta filter, and a cyan filter, and may further include a white filter, but example embodiments are not limited thereto.

In some example embodiments, the grid pattern 160 may be formed on the surface insulating film 150. The grid pattern 160 is formed in a grid form from a planar viewpoint and may be interposed between the color filters 180. In some embodiments, the grid pattern 160 may be disposed to overlap the second separation pattern 120 in the third direction Z.

In some example embodiments, the grid pattern 160 may include a metal pattern 162 and a low refractive index pattern 164. The metal pattern 162 and the low refractive index pattern 164 may be sequentially stacked on, for example, the surface insulating film 150.

The metal pattern 162 may include, for example, but is not limited to, at least one of titanium (Ti), titanium nitride (TiN), tantalum (Ta), tantalum nitride (TaN), tungsten (W), aluminum (Al), copper (Cu), and combinations thereof. The metal pattern 162 inhibits or prevents the electric charges generated by ESD (electrostatic discharge) or the like from accumulating on the surface of the first semiconductor substrate 102 (e.g., the second surface 102b) to effectively inhibit or prevent the ESD bruise defect.

The low refractive index pattern 164 may include a low refractive index material having a lower refractive index than that of silicon (Si). For example, the low refractive index pattern 164 may include, but is not limited to, at least one of silicon oxide, aluminum oxide, tantalum oxide, and combinations thereof. The low refractive index pattern 164 may improve the light collection efficiency by refracting or reflecting light that is incident obliquely.

In some example embodiments, a first protective film 170 may be formed on the surface insulating film 150 and the grid pattern 160. For example, the first protective film 170 may conformally extend along the profiles of the surface insulating film 150 and the grid pattern 160. The first protective film 170 may include, for example, but is not limited to, aluminum oxide. Such a first protective film 170 may prevent damage to the surface insulating film 150 and the grid pattern 160.

The microlens 190 may be formed on the color filter 180. The microlens 190 may be arranged to correspond to each unit pixel (e.g., the first unit pixel UP1). For example, the plurality of microlenses 190 may be arranged two-dimensionally (e.g., in the form of a matrix) in a plane including the first direction X and the second direction Y.

The microlens 190 has a convex shape and may have a desired (or, alternatively predetermined) radius of curvature. As a result, the microlens 190 may collect the light that is incident on the photoelectric conversion region 101. The microlens 190 may include, for example, but is not limited to, a light-transmitting resin.

In some example embodiments, a second protective film 195 may be formed on the microlens 190. The second protective film 195 may extend along the surface of the microlens 190. The second protective film 195 may include, for example, an inorganic oxide film. For example, the second protective film 195 may include, but is not limited to, at least one of silicon oxide, titanium oxide, zirconium oxide, hafnium oxide, and combinations thereof. In some embodiments, the second protective film 195 may include a low temperature oxide (LTO).

The second protective film 195 may protect the microlens 190 from the outside. For example, the second protective film 195 may protect the microlens 190 including an organic substance, by including an inorganic oxide film. Further, the second protective film 195 may improve the quality of the image sensor, by improving the light collection efficiency of the microlens 190. For example, the second protective film 195 may reduce reflection, refraction, scattering, and the like of incident light that reaches the space between the microlenses 190, by filling the space between the microlenses 190.

An image sensor having reduced or miniaturized unit pixels is desired or required to reduce the size of electronic devices and improve the quality of image sensor.

The image sensor according to some example embodiments may implement a SOI transistor, using the cell substrate 100 which is an SOI substrate. Specifically, as described above, the first operating gate structure G1 and the second semiconductor substrate 106 may form the SOI transistor. This makes it possible to provide an image sensor having reduced or miniaturized unit pixels by suppressing a single channel effect (SCE).

Further, the image sensor according to some example embodiments may provide finer unit pixels by minimizing the formation of the element separation pattern, and may improve the quality of the image sensor. Specifically, as described above, the second and third active regions AR2 and AR3 formed in the first semiconductor substrate 102 may be electrically separated from the first active region AR1 formed in the second semiconductor substrate 106 by the buried insulating film 104. That is, in the image sensor according to some example embodiments, separate element separation patterns (e.g., the first element separation patterns 110 and 120) are not desired or required to separate the first active region AR1 from the second and third active regions AR2 and AR3 in the first unit pixel UP1. Accordingly, the consumption area of the unit pixel is saved, and it is possible to provide an image sensor capable of reducing or miniaturizing the pixels. Further, as the formation of the element separation pattern (e.g., the first element separation patterns 110 and 120) is reduced, a dark current flowing along the surface of the element separation pattern may be reduced. This makes it possible to provide an image sensor having improved quality.

Further, the image sensor according to some example embodiments may implement circuit elements of different conductive types from each other, depending on the active region formed in the unit pixel. This makes it possible to provide an image sensor capable of implementing a circuit element optimized depending on the design. For example, as described above, the first transfer gate structure VTG1 and the first semiconductor substrate 102 may form an NMOS transistor in the first unit pixel UP1, and the first operating gate structure G1 and the second semiconductor substrate 106 may form a PMOS transistor in the first unit pixel UP1.

As an example, a transfer transistor implemented as an NMOS transistor exhibits improved current characteristics compared with a transfer transistor implemented as a PMOS transistor. Further, the source follower transistor implemented as the PMOS transistor exhibits reduced flicker noise (1/f noise) compared with the source follower transistor implemented as the NMOS transistor. As mentioned above, in the image sensor according to some example embodiments, a transfer transistor (e.g., TG of FIG. 2) implemented as the NMOS transistor is provided, and a source follower transistor (e.g., SF of FIG. 2) implemented as the PMOS transistor may be provided. This makes it possible to provide an image sensor having improved quality.

Referring to FIG. 5b, in the image sensor according to some example embodiments, the first surface 102a of the second region II of the first semiconductor substrate 102 is formed to be higher than the first surface 102a of the first region I of the first semiconductor substrate 102.

For example, the first surface 102a of the second region II of the first semiconductor substrate 102 may be formed to be higher than the first surface 102a of the first region I of the first semiconductor substrate 102 and lower than the upper surface of the buried insulating film 104. In this case, a step H2 between the second region II of the first semiconductor substrate 102 and the second semiconductor substrate 106 may be relieved. For example, the step between the second region II of the first semiconductor substrate 102 and the second semiconductor substrate 106 may be about 10 nm to about 50 nm (or more or less).

Referring to FIG. 5c, in the image sensor according to some example embodiments, the upper surface of the first separation pattern 110 adjacent to the second region II of the first semiconductor substrate 102 is formed to be lower than the upper surface of the first separation pattern 110 adjacent to the first region I of the first semiconductor substrate 102.

For example, the upper surface of the first separation pattern 110 adjacent to the second region II of the first semiconductor substrate 102 may be disposed on the same or substantially the same plane as the first surface 102a of the first semiconductor substrate 102. Unlike the shown example, the upper surface of the first separation pattern 110 adjacent to the second region II of the first semiconductor substrate 102 may protrude from the first surface 102a of the first semiconductor substrate 102.

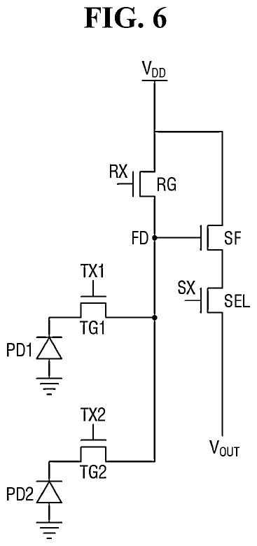

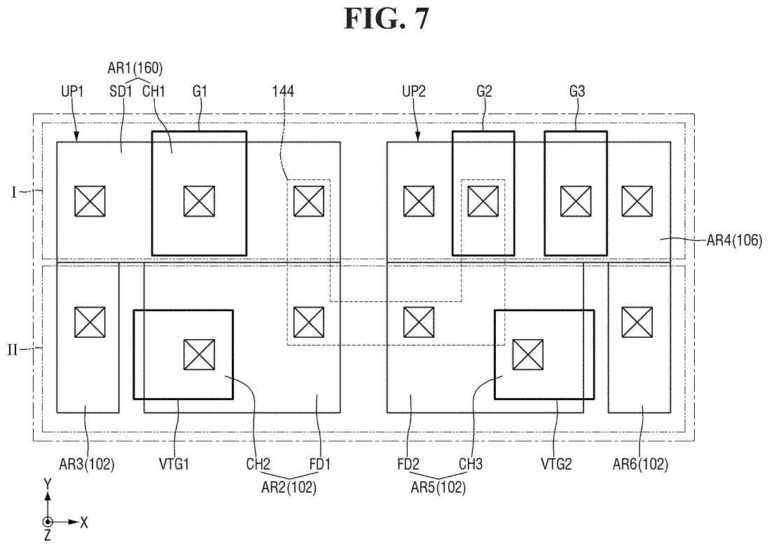

FIG. 6 is another example circuit diagram for explaining an image sensor according to some example embodiments. FIG. 7 is a schematic layout diagram for explaining the image sensor according to FIG. 6. For convenience of explanation, repeated parts explained using FIGS. 1 to 5 will be briefly described or omitted.

Referring to FIG. 6, the image sensor according to some example embodiments may include a first photoelectric conversion element PD1 and a second photoelectric conversion element PD2 that share a floating diffusion region FD.

The first photoelectric conversion element PD1 and the second photoelectric conversion element PD2 may each generate electric charges in proportion to the amount of light incident from the outside. The first photoelectric conversion element PD1 may be coupled to the first transfer transistor TG1 that transfers the generated and accumulated electric charges to the floating diffusion region FD. The second photoelectric conversion element PD2 may be coupled to the second transfer transistor TG2 that transfers the generated and accumulated electric charges to the floating diffusion region FD.

One end of the first transfer transistor TG1 may be connected to the first photoelectric conversion element PD1, and the other end of the first transfer transistor TG1 may be connected to the floating diffusion region FD. The first transfer transistor TG1 may be formed of a transistor driven by a desired (or, alternatively predetermined) bias (e.g., the first transfer signal TX1). One end of the second transfer transistor TG2 may be connected to the second photoelectric conversion element PD2, and the other end of the second transfer transistor TG2 may be connected to the floating diffusion region FD. The second transfer transistor TG2 may be formed of a transistor driven by a determined (or, alternatively predetermined) bias (e.g., the second transfer signal TX2).

Referring to FIG. 7, the image sensor according to some example embodiments includes a first unit pixel UP1 and a second unit pixel UP2 adjacent to each other.

The first unit pixel UP1 and the second unit pixel UP2 may be defined by the element separation patterns 110 and 120, respectively. For example, the element separation patterns 110 and 120 may surround each of the first unit pixel UP1 and the second unit pixel UP2.

The first active region AR1, the second active region AR2, the third active region AR3, the first operating gate structure G1 and the first transfer gate structure VTG1 described above using FIGS. 3 to 5c may be formed in the first unit pixel UP1.

A fourth active region AR4, a fifth active region AR5, a sixth active region AR6, a second operating gate structure G2, a third operating gate structure G3, and a second transfer gate structure VTG2 may be formed in the second unit pixel UP2.

The first and fourth active regions AR1 and AR4 may be defined in the first region I. That is, the first and fourth active regions AR1 and AR4 may be defined in the second semiconductor substrate 106. The second, third, fifth and sixth active regions AR2, AR3, AR5, and AR6 may be defined in the second region II. That is, the second, third, fifth and sixth active regions AR2, AR3, AR5 and AR6 may be defined in the second region II of the first semiconductor substrate 102.

The second operating gate structure G2 and the third operating gate structure G3 may be formed on the fourth active region AR4. When the second operating gate structure G2 and the third operating gate structure G3 are each turned on, the second operating gate structure G2 and the third operating gate structure G3 may each form a channel of the first conductive type in the second semiconductor substrate 106 (or in the fourth active region AR4).

In some example embodiments, the first operating gate structure G1 and the first active region AR1 may form a reset transistor (e.g., RG of FIG. 6), the second operating gate structure G2 and the fourth active region AR4 may form a source follower transistor (e.g., SF of FIG. 6), and the third operating gate structure G3 and the fourth active region AR4 may form a selection transistor (e.g., SEL of FIG. 6).

The second transfer gate structure VTG2 may be formed on the fifth active region AR5 of the first semiconductor substrate 102. The second transfer gate structure VTG2 may define a third channel region CH3 in the fifth active region AR5 that overlaps the second transfer gate structure VTG2. Further, a second floating diffusion region FD2 may be formed in the fifth active region AR5 adjacent to the side surface of the second transfer gate structure VTG2. The second floating diffusion region FD2 may have the second conductive type.

In some example embodiments, the first transfer gate structure VTG1 and the second active region AR2 may form a first transfer transistor (e.g., TG1 of FIG. 6), and the second transfer gate structure VTG2 and the fifth active region AR5 may form a second transfer transistor (e.g., TG2 of FIG. 6).

In some example embodiments, the first unit pixel UP1 and the second unit pixel UP2 may share a floating diffusion region (e.g., FD of FIG. 6). For example, the first floating diffusion region FD1 and the second floating diffusion region FD2 may be electrically connected by the first wiring pattern 144.

In some example embodiments, the first floating diffusion region FD1 and the second floating diffusion region FD2 may be electrically connected to the drain region of the first operating gate structure G1 by the first wiring pattern 144. Accordingly, when the first operating gate structure G1 forming the reset transistor (e.g., RG of FIG. 6) is turned on, the first floating diffusion region FD1 and the second floating diffusion region FD2 may be reset.

In some example embodiments, the first floating diffusion region FD1 and the second floating diffusion region FD2 may be electrically connected to the gate electrode of the second operating gate structure G2 by the first wiring pattern 144. Therefore, the second operating gate structure G2 forming the source follower transistor (e.g., SF of FIG. 6) may amplify a change in electric potential of the first floating diffusion region FD1 and the second floating diffusion region FD2.

In some example embodiments, a ground voltage may be applied to the sixth active region AR6. For example, the sixth active region AR6 may be formed by ion-implanting the p-type impurity of high concentration into the p-type first semiconductor substrate 102.

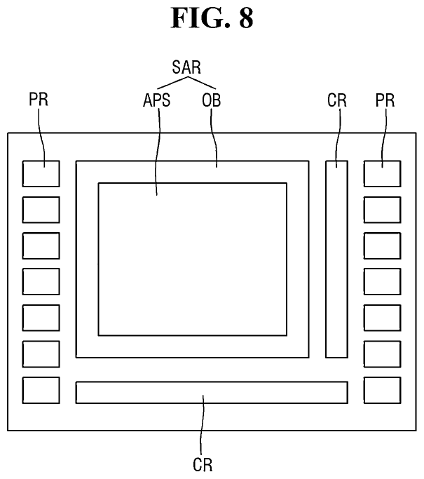

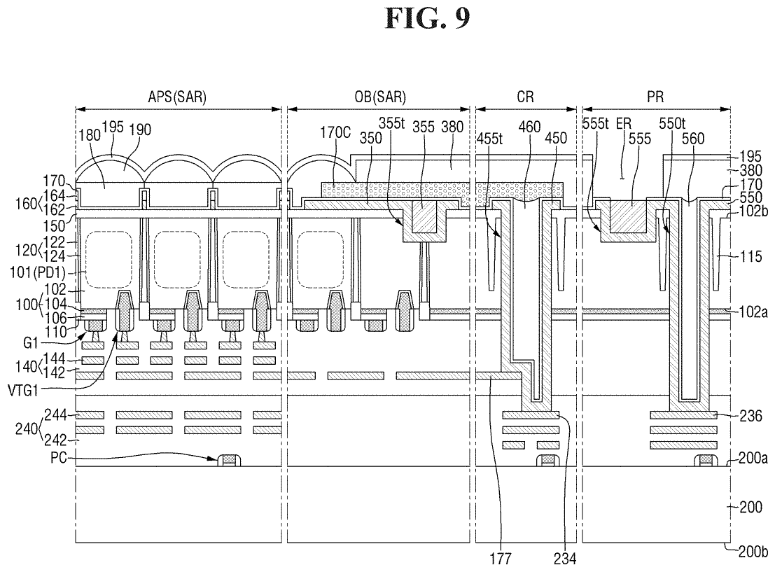

FIG. 8 is an example layout diagram for explaining an image sensor according to some example embodiments. FIG. 9 is a schematic cross-sectional view for explaining the image sensor of FIG. 8. For convenience of explanation, repeated parts explained using FIGS. 1 to 7 will be briefly described or omitted.

Referring to FIGS. 8 and 9, the image sensor according to some example embodiments includes a sensor array region SAR, a connecting region CR, and a pad region PR.

The sensor array region SAR may include a region corresponding to the active pixel sensor array 10 of FIG. 1. For example, a plurality of unit pixels arranged two-dimensionally (e.g., in the form of a matrix) may be formed in the sensor array region SAR.

The sensor array region SAR may include a photo-receiving region APS and a photo-shielding region OB. Active pixels that receive light and generate an active signal may be arranged in the photo-receiving region APS. Optical black pixels that shield the light and generate an optical black signal may be arranged in the photo-shielding region OB. Although the photo-shielding region OB may be formed, for example, along the periphery of the photo-receiving region APS, this is only an example embodiment.

In some example embodiments, the photoelectric conversion region 101 may not be formed in a part of the photo-shielding region OB. For example, the photoelectric conversion region 101 may be formed in the first semiconductor substrate 102 of the photo-shielding region OB adjacent to the photo-receiving region APS, but may not be formed in the first semiconductor substrate 102 of the photo-shielding region OB separated from the photo-receiving region APS.

In some example embodiments, dummy pixels (not shown) may be formed in the photo-receiving region APS that is adjacent to the photo-shielding region OB.

The connecting region CR may be formed around the sensor array region SAR. Although the connecting region CR may be formed on one side of the sensor array region SAR, this is merely an example embodiment. Wirings are formed in the connecting region CR, and may be configured to transmit and receive electrical signals of the sensor array region SAR.

The pad region PR may be formed around the sensor array region SAR. Although the pad region PR may be formed to be adjacent to the edge of the image sensor according to some example embodiments, this is merely an example. The pad region PR is connected to an external device or the like, and may be configured to transmit and receive electrical signals between the image sensor according to some embodiments and the external device.

Although the connecting region CR is shown as being interposed between the sensor array region SAR and the pad region PR, this is merely an example embodiment. The placement of the sensor array region SAR, the connecting region CR and the pad region PR maybe varied as desired or needed.

The first wiring structure 140 may include a first wiring pattern 144 in the sensor array region SAR and a second wiring pattern 177 in the connecting region CR. The first wiring pattern 144 may be electrically connected to the unit pixels of the sensor array region SAR. For example, the first wiring pattern 144 may be connected to the first operating gate structure G1 and the first transfer gate structure VTG1. At least a part of the second wiring pattern 177 may be electrically connected to at least a part of the first wiring pattern 144. Accordingly, the second wiring pattern 177 may be electrically connected to the unit pixels of the sensor array region SAR.

The image sensor according to some example embodiments may include a peripheral circuit board 200 and a second wiring structure 240.

The peripheral circuit board 200 may be bulk silicon, SOI (silicon-on-insulator), etc. The peripheral circuit board 200 may be a silicon substrate or may include other substances, for example, silicon germanium, indium antimonide, lead tellurium compounds, indium arsenic, indium phosphide, gallium arsenide or gallium antimonide, but example embodiments are not limited thereto. The peripheral circuit board 200 may be an epitaxial layer formed on a base substrate.

The peripheral circuit board 200 may include a third surface 200a and a fourth surface 200b that are opposite to each other. In some example embodiments, the third surface 200a of the peripheral circuit board 200 may be opposite to the first surface 102a of the first semiconductor substrate 102.

A peripheral circuit element PC may be formed on the third surface 200a of the peripheral circuit board 200. The peripheral circuit element PC may be electrically connected to the sensor array region SAR, and transmit and receive electrical signals to and from each unit pixel of the sensor array region SAR. For example, the peripheral circuit element PC may include electronic elements that constitute one or more of the row decoder 20, the row driver 30, the column decoder 40, the timing generator 50, the correlated double sampler 60, the analog-to-digital converter 70 and the I/O buffer 80 of FIG. 1.

The second wiring structure 240 may be formed on the third surface 200a of the peripheral circuit board 200. For example, the second wiring structure 240 may include a second inter-wiring insulating film 242 and various wiring patterns 244, 234, and 236 in the second inter-wiring insulating film 242. In FIG. 9, the number of layers and the arrangement of the wiring patterns 244, 234, and 236 are merely examples, and other example embodiments may include more or less layers and different arrangements of the wiring patterns 244, 234 and 236.

At least a part of the wiring patterns 244, 234, and 236 of the second wiring structure 240 may be connected to the peripheral circuit element PC. In some example embodiments, the second wiring structure 240 may include a third wiring pattern 244 in the sensor array region SAR, a fourth wiring pattern 234 in the connecting region CR, and a fifth wiring pattern 236 in the pad region PR. In some example embodiments, the fourth wiring pattern 234 may be the uppermost wiring among the plurality of wirings in the connecting region CR, and the fifth wiring pattern 236 may be the uppermost wiring among the plurality of wirings in the pad region PR.

The first wiring structure 140 and the second wiring structure 240 may be bonded to each other. For example, as shown in FIG. 9, the upper surface of the second wiring structure 240 may be attached to a lower surface of the first wiring structure 140. The first wiring structure 140 and the second wiring structure 240 may be bonded, for example, by a wafer bonding process.

The image sensor according to some example embodiments may include a first connecting structure 350, a second connecting structure 450, and a third connecting structure 550.

The first connecting structure 350 may be formed in the photo-shielding region OB. The first connecting structure 350 may be formed on the surface insulating film 150 of the photo-shielding region OB. The first connecting structure 350 may come into contact with a part of the second separation pattern 120. For example, a first trench 355t that exposes the second separation pattern 120 may be formed in the first semiconductor substrate 102 and the surface insulating film 150 of the photo-shielding region OB. The first connecting structure 350 may be formed in the first trench 355t and be in contact with the second separation pattern 120 in the photo-shielding region OB. In some example embodiments, the first connecting structure 350 may extend along profiles of the side surfaces and the lower surface of the first trench 355t.

The first connecting structure 350 may include, for example, but is not limited to, at least one of titanium (Ti), titanium nitride (TiN), tantalum (Ta), tantalum nitride (TaN), tungsten (W), aluminum (Al), copper (Cu) and a combination thereof.

In some example embodiments, the first connecting structure 350 may be electrically connected to the second separation pattern 120 and apply a ground voltage or a negative voltage to the second separation pattern 120. As a result, the electric charges generated by ESD or the like may be discharged to the first connecting structure 350 through the second separation pattern 120. The ESD bruise defect may be effectively prevented accordingly

In some example embodiments, a first pad 355 that fills or substantially fills the first trench 355t may be formed on the first connecting structure 350. The first pad 355 may include, for example, but is not limited to, at least one of tungsten (W), copper (Cu), aluminum (Al), gold (Au), silver (Ag), and alloys thereof.

In some example embodiments, the first protective film 170 may cover the first connecting structure 350 and the first pad 355. For example, the first protective film 170 may extend along the profiles of the first connecting structure 350 and the first pad 355.

The second connecting structure 450 may be formed in the connecting region CR. The second connecting structure 450 may be formed on the surface insulating film 150 of the connecting region CR. The second connecting structure 450 may electrically connect the first wiring structure 140 and the second wiring structure 240. For example, a second trench 455t that exposes the second wiring pattern 177 and the fourth wiring pattern 234 may be formed in the connecting region CR. The second connecting structure 450 may be formed in the second trench 455t and connect the second wiring pattern 177 and the fourth wiring pattern 234. In some example embodiments, the second connecting structure 450 may extend along profiles of the side surfaces and the lower surface of the second trench 455t.

The second connecting structure 450 may include, for example, but is not limited to, at least one of titanium (Ti), titanium nitride (TiN), tantalum (Ta), tantalum nitride (TaN), tungsten (W), aluminum (Al), copper (Cu), and combinations thereof. In some embodiments, the second connecting structure 450 may be formed at the same level as the first connecting structure 350.

In some example embodiments, the first protective film 170 may cover the second connecting structure 450. For example, the first protective film 170 may extend along the profile of the second connecting structure 450.

In some example embodiments, a first filling insulating film 460 that fills the second trench 455t may be formed on the second connecting structure 450. The first filling insulating film 460 may include, for example, but is not limited to, at least one of silicon oxide, aluminum oxide, tantalum oxide, and combinations thereof.

The third connecting structure 550 may be formed in the pad region PR. The third connecting structure 550 may be formed on the surface insulating film 150 of the pad region PR. The third connecting structure 550 may electrically connect the second wiring structure 240 to an external device or the like. For example, a third trench 550t that exposes the fifth wiring pattern 236 may be formed in the pad region PR. The third connecting structure 550 may be formed in the third trench 550t and be in contact with the fifth wiring pattern 236. Further, a fourth trench 555t may be formed in the first semiconductor substrate 102 of the pad region PR. The third connecting structure 550 may be formed in the fourth trench 555t and exposed. In some example embodiments, the third connecting structure 550 may extend along profiles of the side surfaces and the lower surface of the third trench 550t and the fourth trench 555t.

The third connecting structure 550 may include, for example, but is not limited to, at least one of titanium (Ti), titanium nitride (TiN), tantalum (Ta), tantalum nitride (TaN), tungsten (W), aluminum (Al), copper (Cu) and combinations thereof. In some embodiments, the third connecting structure 550 may be formed at the same or substantially the same level as the first connecting structure 350 and the second connecting structure 450.

In some example embodiments, a second filling insulating film 560 that fills the third trench 550t may be formed on the third connecting structure 550. The second filling insulating film 560 may include, for example, but is not limited to, at least one of silicon oxide, aluminum oxide, tantalum oxide, and combinations thereof. In some embodiments, the second filling insulating film 560 may be formed at the same or substantially the same level as the first filling insulating film 460.

In some embodiments, a second pad 555 that fills or substantially fills the fourth trench 555t may be formed on the third connecting structure 550. The second pad 555 may include, for example, but is not limited to, at least one of tungsten (W), copper (Cu), aluminum (Al), gold (Au), silver (Ag), and alloys thereof. In some example embodiments, the second pad 555 may be formed at the same or substantially the same level as the first pad 355.

In some example embodiments, the first protective film 170 may cover the third connecting structure 550. For example, the first protective film 170 may extend along the profile of the third connecting structure 550. In some example embodiments, the first protective film 170 may expose the second pad 555.

In some example embodiments, an isolation pattern 115 may be formed in the first semiconductor substrate 102. Although the isolation pattern 115 is shown as being formed around the second connecting structure 450 and around the third connecting structure 550, this is only an example embodiment. For example, the isolation pattern 115 may also be formed around the first connecting structure 350. The isolation pattern 115 may include, for example, but is not limited to, at least one of silicon oxide, silicon nitride, silicon oxynitride, aluminum oxide, hafnium oxide, and combinations thereof.

In some example embodiments, the width of the isolation pattern 115 may decrease from the second surface 102b of the first semiconductor substrate 102 toward the first surface 102a of the first semiconductor substrate 102. This may be due to the characteristics of the etching process for forming the isolation pattern 115. For example, the isolation pattern 115 may be a BDTI (backside deep trench isolation) formed by a DTI (deep trench isolation) process on the back side of the first semiconductor substrate 102. In some example embodiments, the isolation pattern 115 may be separated from the first surface 102a of the first semiconductor substrate 102.

In some example embodiments, a photo-shielding color filter 170C may be formed on the first connecting structure 350 and the second connecting structure 450. For example, the photo-shielding color filter 170C may be formed to cover a part of the first protective film 170 in the photo-shielding region OB and the connecting region CR. The photo-shielding color filter 170C may shield the light incident on the first semiconductor substrate 102.

In some example embodiments, a third protective film 380 may be formed on the photo-shielding color filter 170C. For example, the third protective film 380 may be formed to cover a part of the first protective film 170 in the photo-shielding region OB, the connecting region CR, and the pad region PR. In some example embodiments, the second protective film 185 may extend along the surface of the third protective film 380. The third protective film 380 may include, for example, but is not limited to, a light-transmitting resin. In some example embodiments, the third protective film 380 may be formed at the same level or substantially the same level as the microlens 190.

In some example embodiments, the second protective film 185 and the third protective film 380 may expose the second pad 555. For example, an exposure opening ER that exposes the second pad 555 may be formed in the second protective film 185 and the third protective film 380. Therefore, the second pad 555 may be connected to an external device or the like and configured to transmit and receive electrical signals between the image sensor according to some example embodiments and the external device. That is, the second pad 555 may be an input/output pad of the image sensor according to some example embodiments.

Hereinafter, a method for fabricating an image sensor according to example embodiments will be described referring to FIGS. 1 to 25.

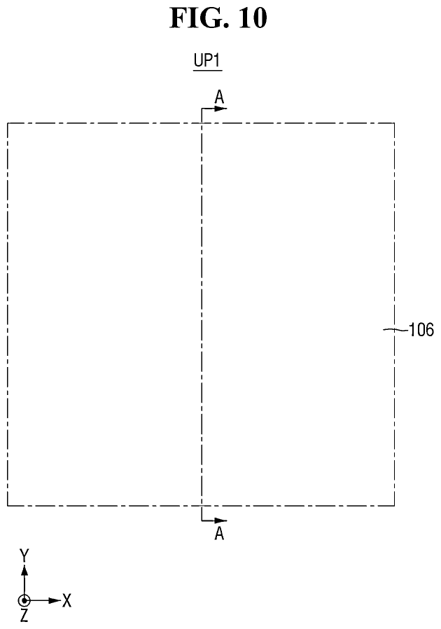

FIGS. 10 to 25 are intermediate step diagrams for explaining a method for fabricating an image sensor according to some example embodiments. For convenience of explanation, repeated parts explained using FIGS. 1 to 9 will be briefly described or omitted.

An image sensor fabricated according to the method for fabricating an image sensor according to some example embodiments may include a plurality of unit pixels. The plurality of unit pixels may be arranged two-dimensionally (e.g., in the form of a matrix) in a plane including, for example, the first direction X and the second direction Y. For convenience of explanation, one unit pixel (hereinafter, a first unit pixel UP1) of the image sensor according to some example embodiments will be mainly described in FIGS. 10 to 25.

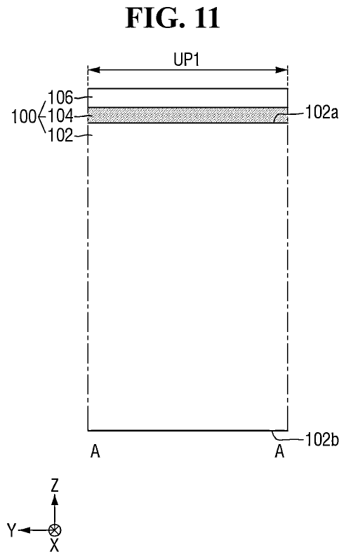

Referring to FIGS. 10 and 11, a cell substrate 100 is provided. For reference, FIG. 11 is a schematic cross-sectional view taken along A-A of FIG. 10.

The cell substrate 100 may be an SOI substrate. For example, the cell substrate 100 may include a first semiconductor substrate 102, a buried insulating film 104, and a second semiconductor substrate 106. The buried insulating film 104 and the second semiconductor substrate 106 may be sequentially stacked on the first surface 102a of the first semiconductor substrate 102.

In some example embodiments, the first semiconductor substrate 102 may have a first conductive type, and the second semiconductor substrate 106 may have a second conductive type opposite to the first conductive type. In the following description, it will be described that the first semiconductor substrate 102 is a p-type and the second semiconductor substrate 106 is an n-type.

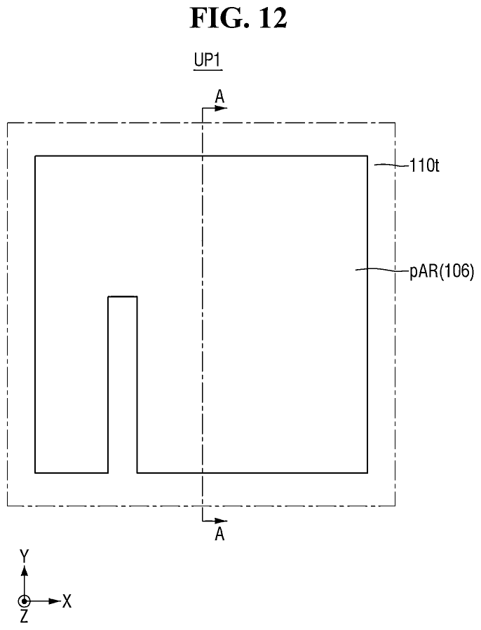

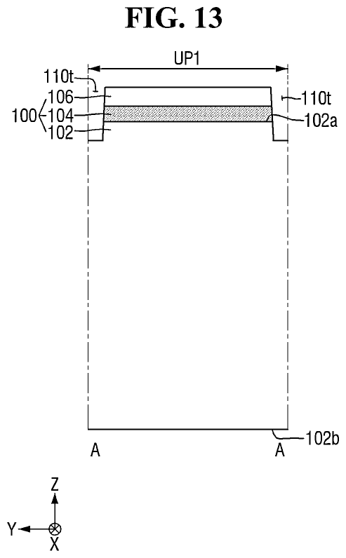

Referring to FIGS. 12 and 13, a first separation trench 110t is formed in the cell substrate 100. For reference, FIG. 13 is a schematic cross-sectional view taken along A-A of FIG. 12.

The first separation trench 110t may define a plurality of unit pixels in the cell substrate 100. For example, the first separation trench 110t may surround the first unit pixel UP1.

The first separation trench 110t may extend from the upper surface of the second semiconductor substrate 106 toward the second surface 102b of the first semiconductor substrate 102. Further, the lower surface of the first separation trench 110t may be formed to be lower than the first surface 102a of the first semiconductor substrate 102. The first separation trench 110t may be formed, for example, by a shallow trench isolation (STI) process on the upper surface of the cell substrate 100. The first separation trench 110t may define a preliminary active region pAR in the first unit pixel UP1.

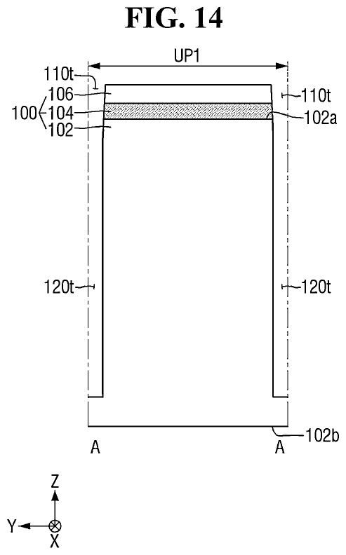

Referring to FIG. 14, a second separation trench 120t is formed in the cell substrate 100.

The second separation trench 120t may extend from a lower surface of the first separation trench 110t toward the second surface 102b of the first semiconductor substrate 102. The second separation trench 120t may be formed, for example, by a shallow trench isolation (DTI) process on the first surface 102a of the second semiconductor substrate 106. The first separation trench 110t may define the first unit pixel UP1 in the second semiconductor substrate 106.

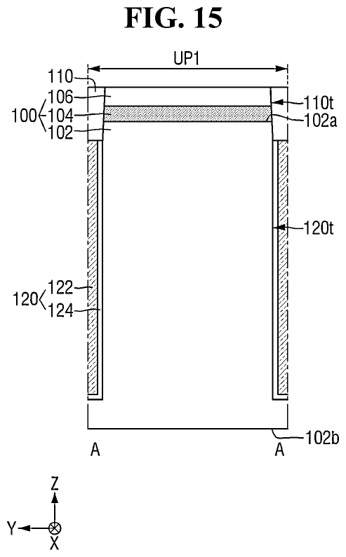

Referring to FIG. 15, the first separation pattern 110 and the second separation pattern 120 are formed in the cell substrate 100.

For example, a second separation pattern 120 that fills the second separation trench 120t may be formed. Subsequently, the first separation pattern 110 that fills the first separation trench 110t may be formed. The first separation pattern 110 and the second separation pattern 120 may each include an insulating material.

In some example embodiments, the second separation pattern 120 may include a filling pattern 122 and a spacer film 124. The filling pattern 122 and the spacer film 124 may be sequentially stacked in the second separation trench 120t.

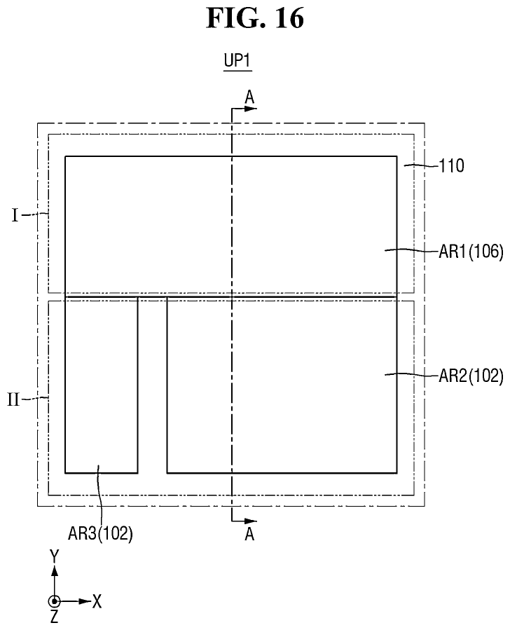

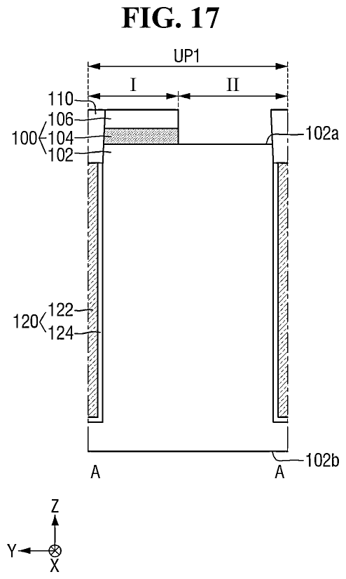

Referring to FIGS. 16 and 17, a part of the first surface 102a of the first semiconductor substrate 102 is exposed. For reference, FIG. 17 is a schematic cross-sectional view taken along A-A of FIG. 16.

For example, the buried insulating film 104 and the second semiconductor substrate 106 disposed on the second region II of the first semiconductor substrate 102 may be selectively removed. As a result, the buried insulating film 104 and the second semiconductor substrate 106 that cover the first region I of the first semiconductor substrate 102 and expose the second region II of the first semiconductor substrate 102 may be formed. Further, the first active region AR1 in the first region I and the second and third active regions AR2 and AR3 in the second region II may be defined.

In the process of removing the buried insulating film 104 and the second semiconductor substrate 106, a part of the first semiconductor substrate 102 may be removed. In this case, unlike the shown example, the first surface 102a of the second region II of the first semiconductor substrate 102 may be formed to be lower than the first surface 102a of the first region I of the first semiconductor substrate 102.

In some example embodiments, the buried insulating film 104 and the second semiconductor substrate 106 may be selectively removed with respect to the first separation pattern 110. In this case, the upper surface of the first separation pattern 110 adjacent to the second region II of the first semiconductor substrate 102 may protrude from the first surface 102a of the first semiconductor substrate 102.

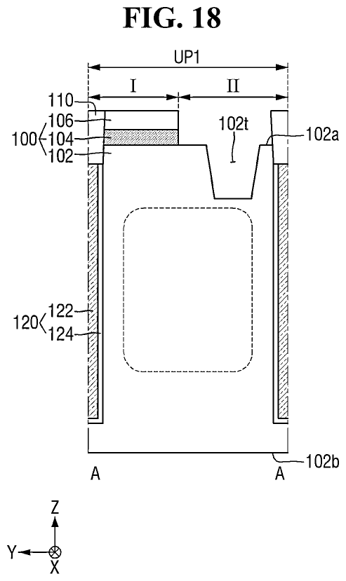

Referring to FIG. 18, a photoelectric conversion region 101 is formed in the first semiconductor substrate 102.

The photoelectric conversion region 101 may have the second conductive type. For example, the photoelectric conversion region 101 may be formed by ion-implanting n-type impurities into the p-type first semiconductor substrate 102.

In some example embodiments, the substrate trench 102t may be formed in the second region II of the first semiconductor substrate 102. The substrate trench 102t may extend from the first surface 102a of the first semiconductor substrate 102 toward the second surface 102b of the first semiconductor substrate 102. In some example embodiments, at least a part of the substrate trench 102t may overlap the photoelectric conversion region 101 in the third direction Z.

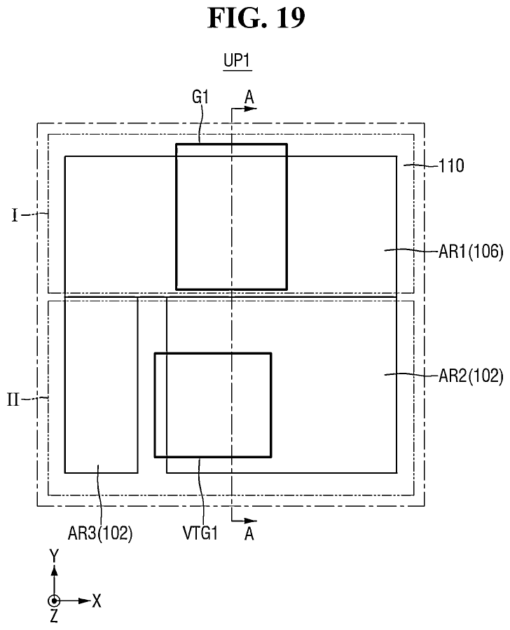

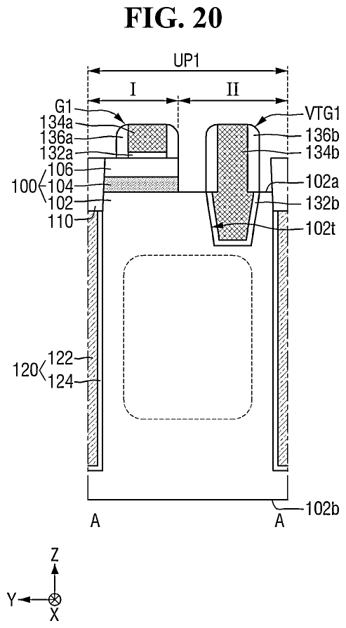

Referring to FIGS. 19 and 20, the first operating gate structure G1 and the first transfer gate structure VTG1 are formed.

The first operating gate structure G1 may be formed on the first active region AR1. For example, an oxide film may be formed by performing an oxidation process on at least a part of the second semiconductor substrate 106. Subsequently, a conductive film may be formed on the oxide film, and the oxide film and the conductive film may be patterned by a patterning process. As a result, the first gate dielectric film 132a and the first gate electrode 134a may be formed on the upper surface of the second semiconductor substrate 106. The first gate spacer 136a may be formed to cover the side surfaces of the first gate dielectric film 132a and the side surfaces of the first gate electrode 134a.

The first transfer gate structure VTG1 may be formed on the second active region AR2. For example, an oxide film may be formed by performing an oxidation process on at least a part of the first semiconductor substrate 102 including the substrate trench 102t. Subsequently, a conductive film may be formed on the oxide film, and the oxide film and the conductive film may be patterned by a patterning process. As a result, the second gate dielectric film 132b and the second gate electrode 134b may be formed on the second region II of the first semiconductor substrate 102. The second gate spacer 136b may be formed to cover a part of the side surfaces of the second gate electrode 134b.

In some example embodiments, the first operating gate structure G1 and the first transfer gate structure VTG1 may be formed at the same or substantially the same level. For example, the oxidation process and the patterning process on the first operating gate structure G1 and the first transfer gate structure VTG1 may be performed simultaneously or substantially simultaneously (e.g., in situ).

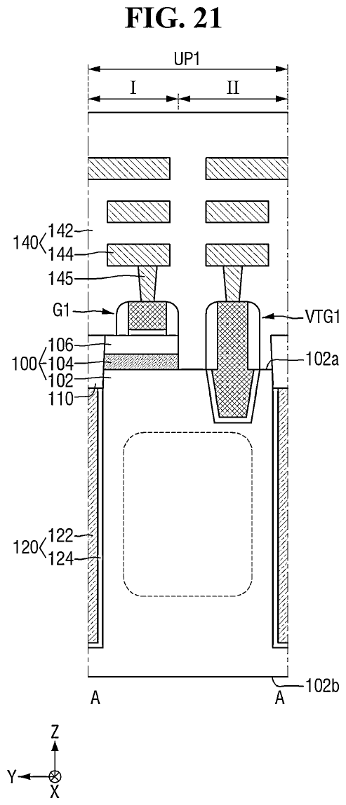

Referring to FIG. 21, the first wiring structure 140 is formed.

The first wiring structure 140 may be formed on the first surface 102a of the first semiconductor substrate 102. The first wiring structure 140 may include a plurality of wiring patterns. For example, the first wiring structure 140 may include a first inter-wiring insulating film 142 and a first wiring pattern 144 in the first inter-wiring insulating film 142.

The first wiring structure 140 may be connected to the first operating gate structure G1 and the first transfer gate structure VTG1. For example, a gate contact 145 that extends in the third direction Z and connects the first operating gate structure G1 and/or the first transfer gate structure VTG1 and the first wiring pattern 144 may be formed in the first inter-wiring insulating film 142.

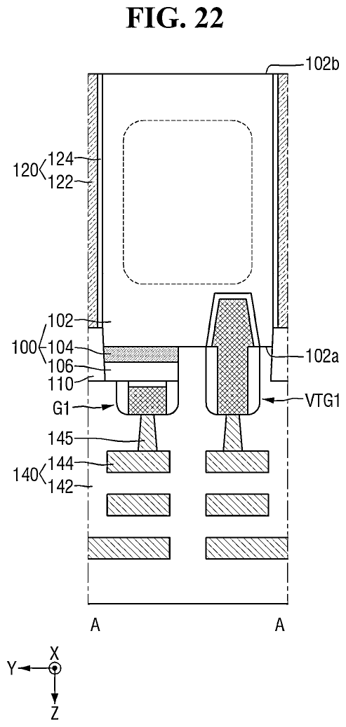

Referring to FIG. 22, a flattening process is performed on the second surface 102b of the first semiconductor substrate 102.

The flattening process may include, for example, but is not limited to, a back grinding process on the first semiconductor substrate 102. In some example embodiments, the second separation pattern 120 may be exposed from the second surface 102b of the first semiconductor substrate 102 by the flattening process.

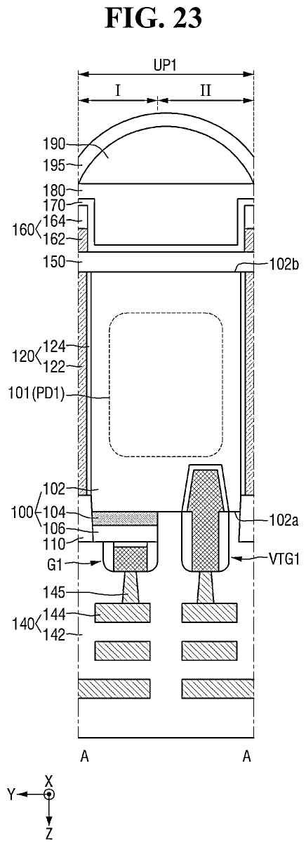

Referring to FIG. 23, a surface insulating film 150, a grid pattern 160, a first protective film 170, a color filter 180, a microlens 190 and a second protective film 195 are formed on the second surface 102b of the first semiconductor substrate 102. The above-mentioned image sensor using FIGS. 3 to 5c may be fabricated accordingly.

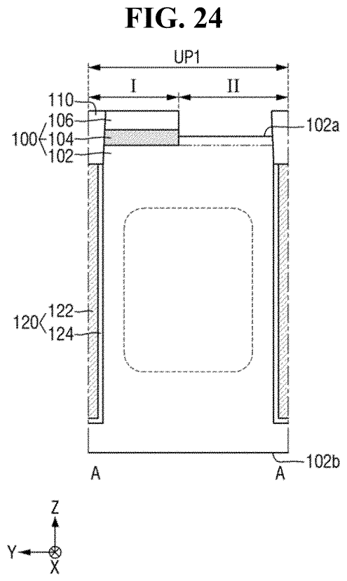

FIG. 24 is an intermediate step diagram for explaining the method for fabricating the image sensor according to some example embodiments. For convenience of explanation, repeated parts explained using FIGS. 1 to 23 will be briefly described or omitted. For reference, FIG. 24 is an intermediate process diagram for explaining the process after FIG. 17.

Referring to FIG. 24, a selective epitaxial growth process is performed on the second region II of the first semiconductor substrate 102.

Since the second region II of the first semiconductor substrate 102 may be exposed by the buried insulating film 104, it may be selectively grown compared to the first region I of the first semiconductor substrate 102. Accordingly, the first surface 102a of the second region II of the first semiconductor substrate 102 may be formed to be higher than the first surface 102a of the first region I of the first semiconductor substrate 102.

In some example embodiments, the second semiconductor substrate 106 may be shielded, while the selective epitaxial growth process is being performed on the second region II of the first semiconductor substrate 102. As a result, the second region II of the first semiconductor substrate 102 may be selectively grown compared to the second semiconductor substrate 106.

The steps described above using FIGS. 18 to 23 may then be performed. Therefore, the image sensor described above using FIG. 5b may be fabricated.

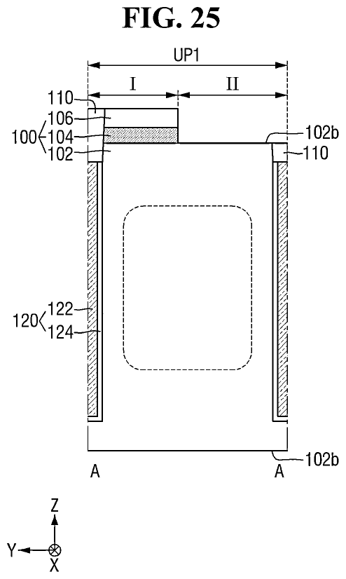

FIG. 25 is an intermediate step diagram for explaining the method for fabricating the image sensor according to some embodiments. For convenience of explanation, repeated parts explained using FIGS. 1 to 23 will be briefly described or omitted. For reference, FIG. 25 is an intermediate step diagram for explaining a step after FIG. 15.

Referring to FIG. 25, in the process of removing the buried insulating film 104 and the second semiconductor substrate 106, a part of the first separation pattern 110 adjacent to the second region II of the first semiconductor substrate 102 is removed.

In such a case, the upper surface of the first separation pattern 110 adjacent to the second region II of the first semiconductor substrate 102 may be formed to be lower than the upper surface of the first separation pattern 110 adjacent to the first region I of the first semiconductor substrate 102. For example, the upper surface of the first separation pattern 110 adjacent to the second region II of the first semiconductor substrate 102 may be disposed on the same plane as the first surface 102a of the first semiconductor substrate 102. Unlike the shown example, the upper surface of the first separation pattern 110 adjacent to the second region II of the first semiconductor substrate 102 may protrude from the first surface 102a of the first semiconductor substrate 102.

The steps described above using FIGS. 18 to 23 may then be performed. Therefore, the image sensor described above using FIG. 5c may be fabricated.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

In concluding the detailed description, those skilled in the art will appreciate that many variations and modifications may be made to the example embodiments without substantially departing from the inventive concepts. Therefore, the example embodiments of the inventive concepts are used in a generic and descriptive sense only and not for purposes of limitation.

What is claimed is:

1. An image sensor comprising:
a first semiconductor substrate;
a photoelectric conversion region in the first semiconductor substrate;
a buried insulating film on the first semiconductor substrate, the buried insulating film covering a first region of the first semiconductor substrate and exposing a second region of the first semiconductor substrate;
a second semiconductor substrate on the buried insulating film;
an operating gate structure defining a first channel of a first conductive type in the second semiconductor substrate; and
a transfer gate structure defining a second channel of a second conductive type different from the first conductive type in the second region of the first semiconductor substrate.

2. The image sensor of claim 1, wherein
the first conductive type is a p-type, and
the second conductive type is an n-type.

3. The image sensor of claim 1, wherein
the first semiconductor substrate has the first conductive type, and
the second semiconductor substrate has the second conductive type.

4. The image sensor of claim 1, wherein
the second region of the first semiconductor substrate defines a substrate trench at least partially overlapping the photoelectric conversion region, and
at least a part of the transfer gate structure fills the substrate trench.

5. The image sensor of claim 4, wherein
a longitudinal direction of the first channel is parallel to an upper surface of the second semiconductor substrate, and
a longitudinal direction of the second channel intersects an upper surface of the first semiconductor substrate.

6. The image sensor of claim 1, further comprising:
a floating diffusion region in the second region of the first semiconductor substrate, the floating diffusion region adjacent to side surfaces of the transfer gate structure and having the second conductive type.

7. The image sensor of claim 1, further comprising:
a source/drain region in the second semiconductor substrate, the source/drain region adjacent to side surfaces of the operating gate structure and having the first conductive type.

8. The image sensor of claim 1, wherein a thickness of the second semiconductor substrate is in a range from 10 nm to 30 nm.

9. The image sensor of claim 1, wherein an upper surface of the second region of the first semiconductor substrate is higher than an upper surface of the first region of the first semiconductor substrate and lower than an upper surface of the buried insulating film.

10. The image sensor of claim 9, wherein a step between the second region of the first semiconductor substrate and the second semiconductor substrate is in a range from 10 nm to 50 nm.

11. An image sensor comprising:
a first semiconductor substrate including a first surface and a second surface opposite to each other;
a photoelectric conversion region in the first semiconductor substrate;
a buried insulating film on the first surface of the first semiconductor substrate, the buried insulating film covering a first region of the first semiconductor substrate and exposing a second region of the first semiconductor substrate;
a second semiconductor substrate on the buried insulating film;
an operating gate structure on the second semiconductor substrate; and
a transfer gate structure on the second region of the first semiconductor substrate, at least a part of the transfer gate structure extending from the first surface of the first semiconductor substrate toward the photoelectric conversion region.

12. The image sensor of claim 11, wherein the transfer gate structure includes
a gate electrode including a first portion disposed in the second region of the first semiconductor substrate and a second portion protruding from the first surface of the first semiconductor substrate,
a gate dielectric film interposed between the first portion of the gate electrode and the first semiconductor substrate, and
a gate spacer extending along side surfaces of the second portion of the gate electrode.

13. The image sensor of claim 12, wherein a width of the first portion of the gate electrode is greater than a width of the second portion of the gate electrode.

14. The image sensor of claim 11, wherein an upper surface of the operating gate structure and an upper surface of the transfer gate structure are on the same plane.

15. The image sensor of claim 11, wherein
the operating gate structure and the second semiconductor substrate define a PMOS transistor, and
the transfer gate structure and the second region of the first semiconductor substrate define an NMOS transistor.

16. The image sensor of claim 11, further comprising:
an element separation pattern defining a plurality of pixel regions in the first semiconductor substrate,
wherein the photoelectric conversion region is in each of the pixel regions, and
an upper surface of the element separation pattern protrudes from the first surface of the first semiconductor substrate.

17. The image sensor of claim 11, wherein the second surface of the first semiconductor substrate is a photo-receiving surface arranged to receive incident light.

18. An image sensor comprising:
a first semiconductor substrate including a first surface and a second surface opposite to each other, the first semiconductor substrate being a p-type;
an element separation pattern defining a plurality of pixel regions in the first semiconductor substrate;
an n-type photoelectric conversion region in the first semiconductor substrate of each of the pixel regions;
a buried insulating film on the first surface of the first semiconductor substrate, the buried insulating film covering a first region of the first semiconductor substrate and exposing a second region of the first semiconductor substrate;
an n-type second semiconductor substrate on the buried insulating film;
an operating gate structure defining a p-type channel in the second semiconductor substrate;
a transfer gate structure defining an n-type channel in the second region of the first semiconductor substrate;
a first wiring structure on the first surface of the first semiconductor substrate, the first wiring structure connected to the operating gate structure and the transfer gate structure; and
a microlens on the second surface of the first semiconductor substrate, the microlens corresponding to each of the pixel regions,
wherein at least a part of the transfer gate structure extends from the first surface of the first semiconductor substrate toward the photoelectric conversion region.

19. The image sensor of claim 18, further comprising:
a peripheral circuit board including a third surface opposite to the first surface of the first semiconductor substrate;
a peripheral circuit element on the third surface of the peripheral circuit board; and
a second wiring structure on the third surface of the peripheral circuit board, the second wiring structure connected to the peripheral circuit element,
wherein the first wiring structure and the second wiring structure are bonded to each other.

20. The image sensor of claim 18, wherein the operating gate structure defines at least one of a reset transistor, a source/follower transistor, and a selection transistor.
